(19) United States
(12) Patent Application Publication
(10) Pub. No.: US 2012/0192793 A1
(43) Pub. Date: Aug. 2, 2012

(54) FILM FORMING APPARATUS

(75) Inventor: Koji FUKUMORI, Nirasaki City (JP)

(73) Assignee: TOKYO ELECTRON LIMITED, Tokyo (JP)

(21) Appl. No.: 13/362,482

(22) Filed: Jan. 31, 2012

(30) Foreign Application Priority Data
Feb. 1, 2011 (JP) 2011-19982

(51) Int. Cl. C23C 16/56; C23C 16/455

(52) U.S. Cl. 118/724; 118/722

(57) ABSTRACT

Provided is a film forming apparatus which forms a film on a substrate held within a film forming container by supplying raw material gas onto the substrate. The apparatus includes: a supply mechanism which supplies the raw material gas into the container; an exhaust mechanism which exhausts gas from the container; a trap unit which is disposed in the course of an exhaust passage through which gas flows from the container to the exhaust mechanism, and traps the raw material gas by extracting a product containing the raw material gas; a purge gas supplying unit which is connected to join the exhaust passage between the container and the trap unit and supplies purge gas into the exhaust passage; and a pressure gauge which is disposed in a purge gas supplying passage through which the purge gas flows from the purge gas supplying unit into the exhaust passage.

### CROSS-REFERENCE TO RELATED APPLICATIONS

This application claims the benefit of Japanese Patent Application No. 2011-019982, filed on Feb. 1, 2011, in the Japan Patent Office, the disclosure of which is incorporated herein in its entirety by reference.

### TECHNICAL FIELD

The present disclosure relates to a film forming apparatus which forms a polyimide film on a substrate.

### BACKGROUND

In recent years, material used for semiconductor devices has expanded from inorganic materials to organic materials, which can optimize the characteristics and manufacturing processes of semiconductor devices due to properties not present in inorganic materials.

An example of such an organic material may include polyimide having a high adhesion and a small leakage current. Therefore, a polyimide film obtained by forming polyimide on a substrate can be used as an insulating film, and can also be used as an insulating film in a semiconductor device.

As a method for forming such a polyimide film, there has been known a deposition and polymerization film forming method using a raw material monomer, for example, pyromellitic dianhydride (PMDA) and 4,4′-oxydianiline (ODA) (also called 4,4′-diaminodiphenylether). The deposition and polymerization film forming method polymerizes PMDA and ODA used as a raw material monomer on a substrate by sublimation. In the related art, there is disclosed a film forming method for forming a polyimide film on a substrate by depositing and polymerizing gas obtained by vaporizing a monomer of PMDA and ODA by means of a vaporizer and supplied into a deposition and polymerization chamber.

In the deposition and polymerization film forming method, however, it is known that the raw material monomer which does not contribute to the deposition and polymerization on the substrate may be extracted in a vacuum pump for exhausting the deposition and polymerization chamber, which may have an adverse effect on the vacuum pump. To avoid this problem, there has been proposed a film forming apparatus having a trap including a water cooling coil.

However, the film forming apparatus for forming a polyimide film on a substrate by supplying such PMDA gas and ODA gas onto the substrate has the following problems.

In order to form the polyimide film on the substrate stably by supplying the PMDA gas and ODA gas onto the substrate, it is preferable to make the amount of supplied raw material gas composed of the PMDA gas and ODA gas on the substrate constant. However, when the amount of exhaustion of a film forming container by means of an exhaust mechanism is varied, an internal pressure of the film forming container during film formation is also varied. In addition, when the internal pressure of the film forming container is varied, the amount of supplied raw material gas is also varied. Accordingly, in order to make the amount of supplied raw material gas constant, there is a need to control the internal pressure of the film forming container precisely every time to obtain stable process conditions. In order to control the internal pressure of the film forming container, there is a need to measure the pressure by means of a pressure gauge disposed in the film forming container or an exhaust passage between the film forming container and the exhaust mechanism. In addition, there is a need to place the above-mentioned trap in the exhaust passage between the exhaust mechanism and a part in which the pressure gauge is disposed.

However, since the temperature of exhaust gas discharged out of the film forming container may be as high as, for example, 260 degrees C., and a product including raw material gas is extracted when the temperature of the exhaust gas is decreased, there is a need to keep the temperature of the exhaust passage to the trap high. Accordingly, the pressure gauge disposed in the exhaust passage requires high heat resistance. However, there are few pressure gauges having such high heat resistance.

It may be contemplated that a pre-trap for trapping some of the products containing raw material gas from the exhaust gas is interposed between the film forming container and the pressure gauge in order to slightly decrease the temperature of a portion of the exhaust passage in which the pressure gauge is disposed. However, this may cause the problem of an increase in the installation area (foot print) of the film forming apparatus since two traps are required.

In addition, the above problem is not limited to polyimide film formed by supplying raw material gas composed of PMDA gas and ODA gas onto a substrate, but is common to other films formed by supplying other raw material gases onto a substrate.

### SUMMARY

The present disclosure is made in view of the foregoing, and provides a film forming apparatus in which heat resistance is not required for a pressure gauge for measuring the pressure of the film forming apparatus and an installation area can be reduced.

According to one embodiment of the present disclosure, there is provided a film forming apparatus which forms a film on a substrate held within a film forming container by supplying raw material gas onto the substrate, including: a supply mechanism which supplies the raw material gas into the film forming container; an exhaust mechanism which exhausts gas from the film forming container; a trap unit which is disposed in the course of an exhaust passage through which gas flows from the film forming container to the exhaust mechanism, and traps the raw material gas by extracting a product containing the raw material gas; a purge gas supplying unit which is connected to join the exhaust passage between the film forming container and the trap unit and supplies purge gas into the exhaust passage; and a pressure gauge which is disposed in the course of a purge gas supplying passage through which the purge gas flows from the purge gas supplying unit into the exhaust passage.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view including a partial longitudinal section showing a configuration of a film forming apparatus according to a first embodiment.

FIG. 2 is a schematic view showing detailed configuration between a chamber and a vacuum pump in the film forming apparatus according to the first embodiment.

FIG. 3 is a longitudinal sectional view showing a configuration of a trap unit in the film forming apparatus according to the first embodiment.

FIG. 4 is a schematic sectional view showing a configuration of a first opening/closing valve.

FIG. 5 is a perspective view showing a purge gas passage space model assumed for the calculation of a flow rate.

FIG. 6 is a graph showing a region satisfying Equations 2 and 5, where the horizontal axis represents a flow rate and the vertical axis represents a distance.

FIG. 7 is a first view showing a state of exhaust passages and valves between the chamber and the vacuum pump in a step of a film forming process according to the first embodiment.

FIG. 8 is a second view showing a state of the exhaust passages and valves between the chamber and the vacuum pump in another step of the film forming process according to the first embodiment.

FIG. 9 is a third view showing a state of the exhaust passages and valves between the chamber and the vacuum pump in another step of the film forming process according to the first embodiment.

FIG. 10 is a fourth view showing a state of the exhaust passages and valves between the chamber and the vacuum pump in another step of the film forming process according to the first embodiment.

FIG. 11 is a schematic view showing detailed configuration between a chamber and a vacuum pump in a film forming apparatus according to a comparative example.

FIG. 12 is a longitudinal sectional view showing a configuration of a trap unit in the film forming apparatus according to the comparative example.

FIG. 13 is a schematic view showing detailed configuration between a chamber and a vacuum pump in an evaluated film forming apparatus.

FIG. 14 is a graph showing temporal dependencies of pressures measured by a monitoring pressure gauge and a pressure gauge.

FIG. 15 is a schematic view showing detailed configuration between a chamber and a vacuum pump in a film forming apparatus according to a second embodiment.

FIG. 16 is a graph showing a region satisfying Equations 2 and 5, where the horizontal axis represents a flow rate and the vertical axis represents a length.

### DETAILED DESCRIPTION

Embodiments of the present disclosure will now be described in detail with reference to the drawings.

### First Embodiment

First, a film forming apparatus according to a first embodiment of the present disclosure will be described. In this embodiment, the film forming apparatus forms a polyimide film on a substrate by supplying a first raw material gas obtained by vaporizing a first raw material composed of aromatic acid dianhydride and a second raw material gas obtained by vaporizing a second raw material composed of aromatic diamine onto the substrate held within a film forming container.

The aromatic acid dianhydride is preferably pyromellitic dianhydride (PMDA) and the aromatic diamine is preferably 4,4′-oxydianiline (ODA) (also called 4,4′-diaminodiphenylether). An example of the substrate on which the polyimide film is formed may include a semiconductor wafer (hereinafter abbreviated as a “wafer W”). Hereinafter, a film forming apparatus which forms a polyimide film on a wafer W held in a film forming container by supplying vaporized PMDA gas and ODA gas onto the wafer W will be described by way of example.

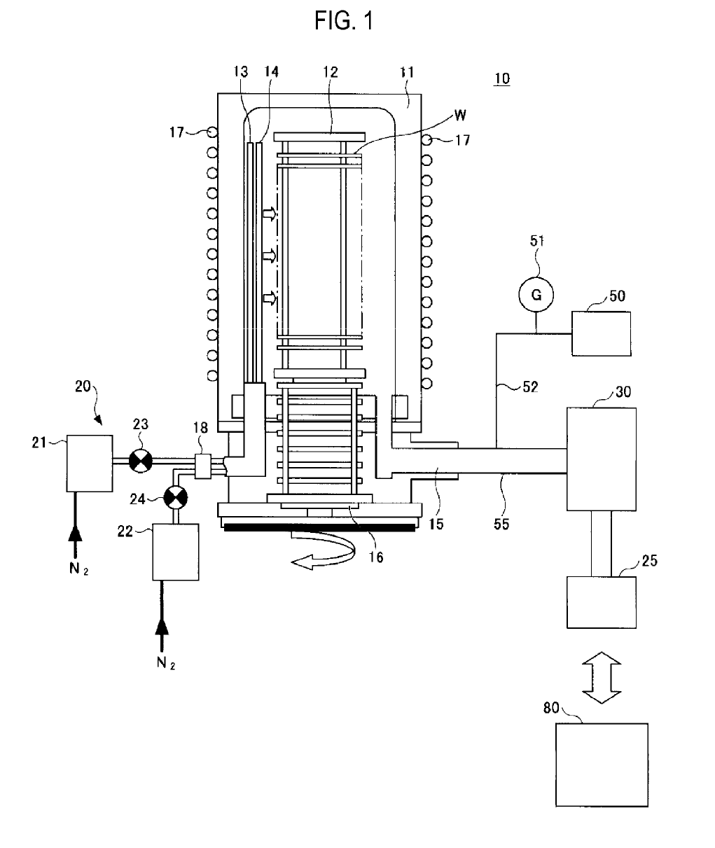

FIG. 1 is a view including a partial longitudinal section showing a configuration of the film forming apparatus according to the first embodiment.

The film forming apparatus 10 of this embodiment includes a film forming container 11, a supply mechanism 20, a vacuum pump 25, a trap unit 30, a purge gas supplying unit 50, a pressure gauge 51 and a controller 80.

The film forming apparatus 10 also includes a wafer boat 12 capable of holding a plurality of wafers W on which a polyimide film is formed within the chamber 11 which can be gas-exhausted by the vacuum pump 25. In addition, injectors 13 and 14 to supply vaporized PMDA (PMDA gas) and vaporized ODA (ODA gas) are disposed within the chamber 11. Openings are formed in the sides of the injectors 13 and 14 and the PMDA gas and ODA gas vaporized by a vaporizer are supplied onto the wafer W, as indicated by arrows in the figure. A polyimide film is formed as the supplied PMDA gas and ODA gas are subjected to a deposition and polymerization reaction on the wafer W. PMDA gas and ODA gas which do not contribute to the formation of the polyimide film flow to be discharged out of an exhaust hole 15. The wafer boat 12 is configured to be rotated by a rotating unit 16 in order to form the polyimide film on the wafer W uniformly. A heater 17 to heat the wafer W within the chamber 11 to a specified temperature is installed in the outside of the chamber 11.

The heater 17 is heated to set the temperature of the chamber 11 within a temperature range in which the supplied PMDA gas and ODA gas are subjected to deposition and polymerization reaction on the wafer W by the controller 80, which will be described later. Specifically, the temperature of the chamber 11 is set to about 200 degrees C.

The chamber 11 corresponds to a film forming container in the present disclosure.

The supply mechanism 20 supplies the PMDA gas and ODA gas into the chamber 11. The supply mechanism 20 includes a first raw material gas supplying unit 21 and a second raw material gas supplying unit 22. The first raw material gas supplying unit 21 is connected to the injector 13 via a valve 23 and an introduction unit 18. The second raw material gas supplying unit 22 is connected to the injector 14 via a valve 24 and the introduction unit 18.

The first raw material gas supplying unit 21 is a first vaporizer 21. The first vaporizer 21 heats and sublimates (or vaporizes) a first raw material composed of PMDA and supplies a first raw material gas composed of PMDA gas obtained by the vaporization into the chamber 11 along with a first carrier gas composed of nitrogen gas (N₂ gas). The first carrier gas is used to carry the first raw material gas composed of the PMDA gas.

The second raw material gas supplying unit 22 is a second vaporizer 22. The second vaporizer 22 heats and vaporizes a second raw material composed of ODA and supplies a second raw material gas composed of ODA gas obtained by the vaporization into the chamber 11 along with a second carrier gas composed of nitrogen gas (N₂ gas). The second carrier gas is used to carry the second raw material gas composed of the ODA gas and bubble liquid ODA.

The PMDA gas supplied from the first raw material gas supplying unit 21 and the ODA gas supplied from the second raw material gas supplying unit 22 are supplied into the chamber 11 via respective injectors 13 and 14 and react with each other on the wafer W to form the polyimide film.

In addition, in this embodiment, a film forming apparatus which performs a batch process for processing a plurality of stacked wafers W in batches will be described by way of example. However, the film forming apparatus 10 of the present disclosure is not limited to the batch type film forming apparatus but may be a single wafer type film forming apparatus which processes a plurality of wafers W individually.

The vacuum pump 25 is connected to the exhaust hole 15 of the chamber 11 and exhausts gas out of the chamber 11. Examples of the vacuum pump 25 used herein may include a roots pump as a dry pump, a screw pump, a rotary pump, a scroll pump, etc. These vacuum pumps have a high displacement adapted to form a film while flowing gas.

The vacuum pump 25 corresponds to an exhaust mechanism in the present disclosure.

The trap unit 30 is disposed in the course of an exhaust passage 55 through which exhaust gas flows from the chamber 11 to the vacuum pump 25. The trap unit 30 traps a product containing raw material gas from the gas discharged from the chamber 11. That is, exhaustion from the exhaust hole 15 is performed by the vacuum pump 25 through the trap unit 30. Details of the trap unit 30 will be described later.

The purge gas supplying unit 50 is connected to join the exhaust passage 55 between the chamber 11 and the trap unit 30 and supplies a purge gas into the exhaust passage 55. The pressure gauge 51 is disposed in the course of a purge gas supplying passage 52 through which the purge gas flows from the purge gas supplying unit 50 into the exhaust passage 55.

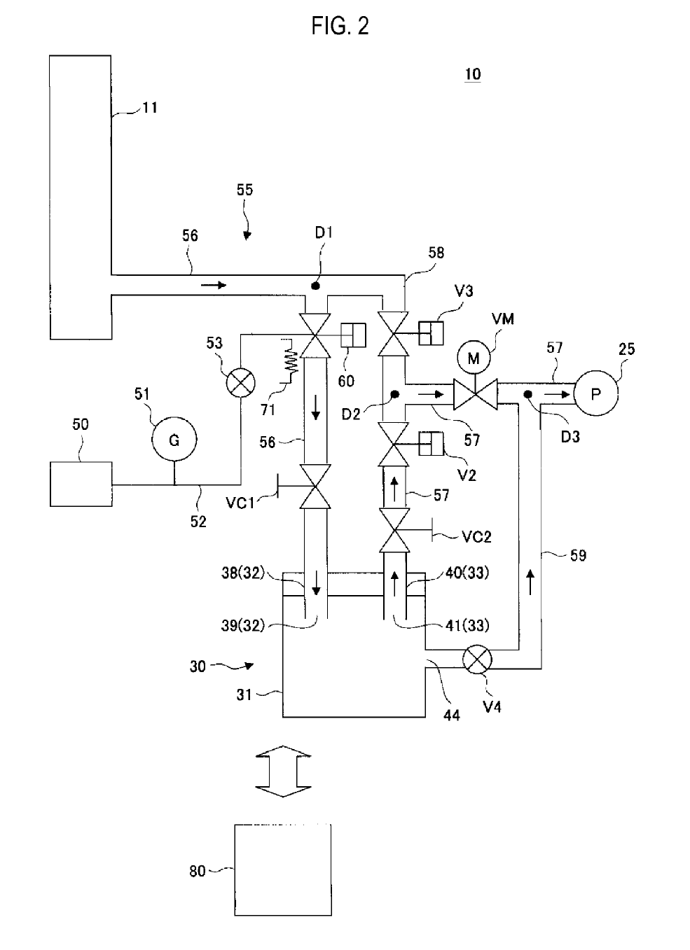

A first opening/closing valve 60 may be interposed between the chamber 11 and the trap unit 30, as described with reference to FIG. 2. The first opening/closing valve 60 is disposed to communicate/interrupt the chamber 11 to/from the trap unit 30. The first opening/closing valve 60 corresponds to an opening/closing valve unit in the present disclosure.

The purge gas supplying unit 50 may be connected to join the exhaust passage 55 at the first opening/closing valve 60. Hereinafter, an example where the purge gas supplying unit 50 is connected to join the exhaust passage 55 via the first opening/closing valve 60 will be described.

FIG. 2 is a schematic view showing detailed configuration between the chamber 11 and the vacuum pump 25 in the film forming apparatus 10 according to this embodiment.

The exhaust passage 55 through which gas discharged out of the chamber 11 flows into the vacuum pump 25 includes a first exhaust passage 56, a second exhaust passage 57, a third exhaust passage 58 and a fourth exhaust passage 59.

The first exhaust passage 56 is a passage through which the gas discharged out of the chamber 11 flows into the trap unit 30. The first opening/closing valve 60 is disposed in the course of the first exhaust passage 56. A first control valve VC1 to control a flow rate of the first exhaust passage 56 is disposed in series with the first opening/closing valve 60 in the course of the first exhaust passage 56. The first exhaust passage 56 is connected to a gas introduction pipe 38 and a gas introduction hole 39 (which will be described later) of the trap unit 30.

The second exhaust passage 57 is a passage through which gas discharged out of the trap unit 30 flows into the vacuum pump 25. The second exhaust passage 57 is connected to a gas escape hole 41 and a gas escape pipe 40 (which will be described later) of the trap unit 30. A second opening/closing valve V2 is disposed in the course of the second exhaust passage 57. The second opening/closing valve V2 is disposed to communicate/interrupt the trap unit 30 to/from the vacuum pump 25. A second control valve VC2 to control a flow rate of the second exhaust passage 57 is disposed in series with the second opening/closing valve V2 in the course of the second exhaust passage 57.

The third exhaust passage 58 connects the first exhaust passage 56 and the second exhaust passage 57 in such a manner that the third exhaust passage 58 detours the trap unit 30. The third exhaust passage 58 connects a first branch point D1 in the course of the first exhaust passage 56 at a location toward the chamber 11 from the first opening/closing valve 60 and a second branch point D2 in the course of the second exhaust passage 57 at a location toward the vacuum pump 25 from the second opening/closing valve V2. A third opening/closing valve V3 is disposed in the course of the third exhaust passage 58. A motor valve VM to control a flow rate of the third exhaust passage 58 is disposed in the third exhaust passage 58 at a location toward the vacuum pump 25 from the third opening/closing valve V3 or in the second exhaust passage 57 at a location toward the vacuum pump 25 from the branch point D2. The third exhaust passage 58 is used to prevent a product deposited in the trap unit 30 from being shifted up as gas in the chamber 11 flows into the trap unit 30 suddenly when the chamber 11 starts to be exhausted after the trap unit 30 is exhausted.

The fourth exhaust passage 59 is disposed to connect the trap unit 30 and the vacuum pump 25 in such a manner that the fourth exhaust passage 59 detours the second opening/closing valve V2 and the second control valve VC2. The fourth exhaust valve 59 connects a second escape hole 44 formed in the trap unit 30 and a third branch point D3 of the second exhaust passage 57 at a location toward the vacuum pump 25 from the motor valve VM. A fourth opening/closing valve V4 is disposed in the course of the fourth exhaust passage 59.

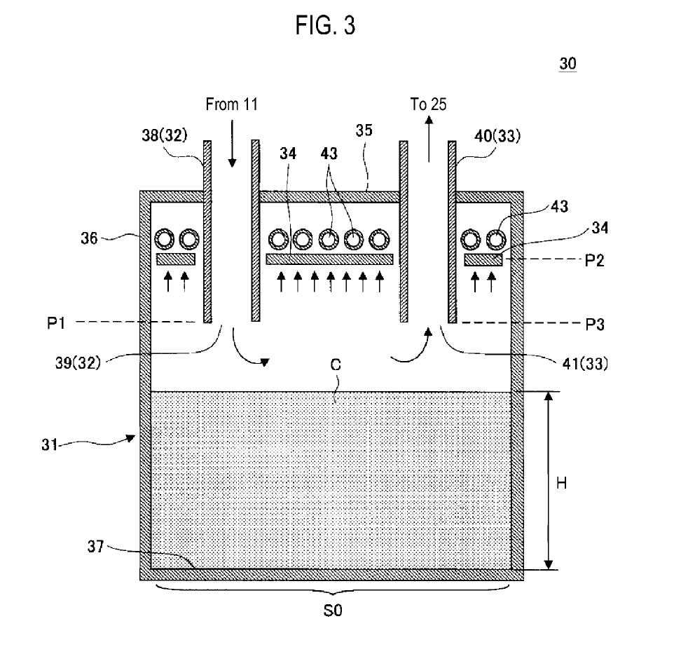

Next, the trap unit 30 will be described with reference to FIGS. 2 and 3. FIG. 3 is a longitudinal sectional view showing a configuration of the trap unit 30 in the film forming apparatus according to this embodiment. The second escape 44 is not shown in FIG. 3.

The trap unit 30 includes a trap container 31, a gas introduction part 32, a gas escape part 33 and a trap plate 34.

The trap container 31 includes a top portion 35, a side portion 36 and a bottom portion 37. The top portion 35, the side portion 36 and the bottom portion 37 are interconnected via, for example, an O-ring (not shown).

The gas introduction part 32 is disposed in the top portion 35 of the trap container 31. The gas introduction part 32 includes a gas introduction pipe 38 and a gas introduction hole 39. The gas introduction pipe 38 is disposed to pass through the top portion 35 of the trap container 31 from top to bottom. The upper part of the gas introduction pipe 38 is connected to the chamber 11 via the first opening/closing valve 60, and the gas introduction hole 39 opened in the trap container 31 is formed in the lower end of the gas introduction pipe 38. Exhaust gas discharged out of the chamber 11 is introduced into the trap container 31 via the gas introduction hole 39.

The gas escape part 33 is also disposed in the top portion 35 of the trap container 31. The gas escape part 33 includes a gas escape pipe 40 and a gas escape hole 41. The gas escape pipe 40 is disposed to pass through the top portion 35 of the trap container 31 from bottom to top and the gas escape hole 41 opened in the trap container 31 is formed in the lower end of the gas escape pipe 40. The upper part of the gas escape pipe 40 is connected to the vacuum pump 25 and exhaust gas in the trap container 31 is exhausted to the vacuum pump 25 via the gas escape hole 41.

The trap plate 34 is substantially horizontally disposed within the trap container 31 at a vertical position P2 higher than a vertical position P1 at which the gas introduction hole 39 is formed. That is, the trap plate 34 is substantially horizontally disposed within the trap container 31 at the vertical position P2 higher than the vertical position P1 at which the gas introduction part 32 introduces exhaust gas into the trap container 31.

In addition, the trap plate 34 may be disposed at the vertical position P2 higher than a vertical position P3 at which the gas escape hole 41 is formed. In the example shown in FIG. 3, since the vertical position P3 of the gas escape hole 41 is substantially equal to the vertical position P1 of the gas introduction hole 39, the trap plate 34 is disposed at the vertical position P2 higher than the vertical positions P1 and P3 at which the gas introduction hole 39 and the gas escape hole 41 are respectively formed.

A water cooling pipe 43 as a cooling mechanism is disposed on the top side of the trap plate 34 within the trap container 31. For example, the water cooling pipe 43 is spirally formed adjacent to the top side of the trap plate 34. The water cooling pipe 43 is provided with an introduction hole (not shown) for introducing cooling water into the water cooling pipe 43 and an escape hole (not shown) for discharging the cooling water out of the water cooling pipe 43. Cooling water flows through the water cooling pipe 43 via the introduction hole from a cooling water supply source (not shown), and out via the escape hole. The water cooling pipe 43 acts to cool exhaust gas.

A mixture of PMDA gas and ODA gas introduced into the trap container 31 through the gas introduction hole 39 is diffused within the trap container 31. At that time, the trap plate 34 is cooled by the water cooling pipe 43 disposed on the top side of the trap plate 34. The PMDA gas and the ODA gas are cooled by the cooled trap plate 34 and are frozen on the bottom side of the trap plate 34, thereby extracting a product C including one of the PMDA gas and the ODA gas. The extracted product C peels off from the bottom side of the trap plate 34 and drops and deposits on the bottom portion 37 of the trap container 31. The remaining gas with the product C extracted flows toward the gas escape hole 41.

In this embodiment, the trap unit 30 is disposed such that it directs downward in the same direction as gravity. However, the direction may be slightly varied as long as the same effects for this embodiment can be achieved.

In this embodiment, the trap plate 34 in the trap unit 30 is substantially horizontally placed. This allows the product C frozen and extracted on the bottom side of the trap plate 34 to drop into the bottom portion 37 of the trap container 31. In addition, since the product C extracted on the bottom side of the trap plate 34 cannot continue to adhere to the trap plate 34, the trap plate 34 remains in substantially the same cooling condition at all times.

An exhaust speed of the vacuum pump 25 is set such that the speed of gas flowing into the trap container 31 is below a range of speeds at which the product deposited on the bottom portion 37 is shifted up. The vertical position P1 of the gas introduction hole 39, the vertical position P3 of the gas escape hole 41 and the vertical position P2 of the trap plate 34 are designed in consideration of the gas speed. For example, when the distance between the vertical position P1 of the gas introduction hole 39 or the vertical position P3 of the gas escape hole 41 and the bottom portion 37 is small, the flowing gas is more likely to shift up PMDA and ODA deposited on the bottom portion 37. Accordingly, the distance between the vertical position P1 of the gas introduction hole 39 or the vertical position P3 of the gas escape hole 41 and the bottom portion 37 is in some instances set to be above a range of distances in which the deposited product is shifted up.

An alien substance take-out part (not shown) is also provided in the bottom portion 37 of the trap container 31 and the deposited product can be taken out by the alien substance take-out part for the sake of easy maintenance.

A temperature control mechanism (not shown) such as a heater or the like may also be provided in the trap unit 30 and its temperature may be controlled by the controller 80, which will be described later, such that the trap unit 30 is set to a predetermined temperature.

In this embodiment, the trap unit 30 is used to trap raw material gas by extracting the product including PMDA and ODA as the raw material gas from the gas discharged out of the chamber 30. As the trap unit 30 adjusts the temperature and flow rate of water flowing through the water cooling pipe 43 by means of the controller 80, the temperature of the trap unit 30 is adjusted to fall within a range of temperatures in which a reaction for the extraction of the product including PMDA and ODA is produced. For example, the temperature of the trap unit 30 is set to be below 120 degrees C.

As the trap unit 30 is interposed between the chamber 11 and the vacuum pump 25, it is possible to prevent the vacuum pump 25 from being broken due to the adhesion of a product such as polyimide or the like to the vacuum pump 25.

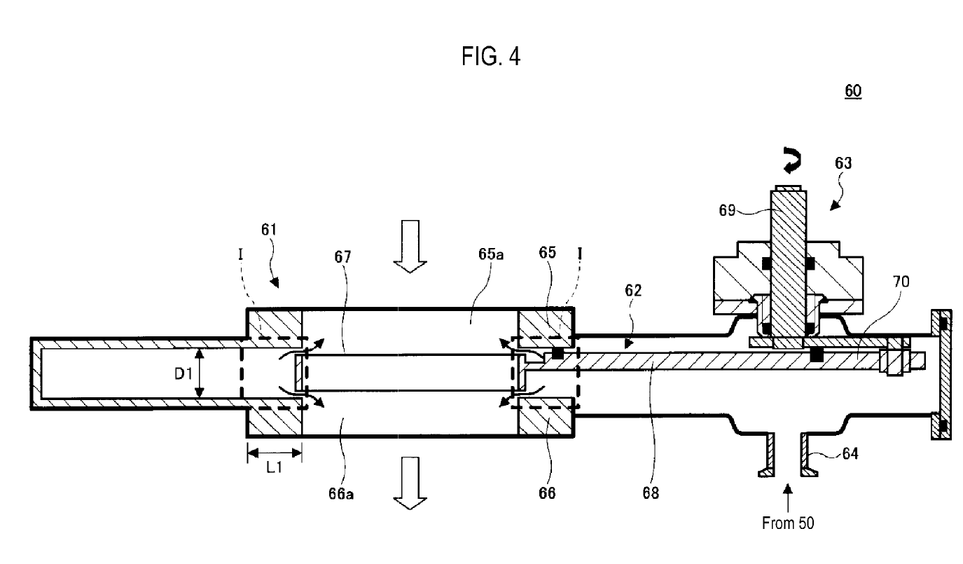

Next, the first opening/closing valve 60 will be described with reference to FIG. 4. FIG. 4 is a schematic sectional view showing a configuration of the first opening/closing valve 60.

The first opening/closing valve 60 includes an opening 61, an opening/closing part 62, a driving part 63 and a purge gas introduction part 64.

The opening 61 includes an upper opening 65 and a lower opening 66. The upper opening 65 and the lower opening 66 are formed to allow the opening/closing part 62 to be inserted therein from the upper and lower sides and have respective holes 65a and 66a having the same inner diameter. The opening/closing part 62 includes a communicating portion 67 formed with a hole having substantially the same diameter as the holes 65a and 66a respectively formed in the upper opening 65 and the lower opening 66, and an interrupt portion 68 for blocking the upper opening 65 and the lower opening 66, and is transversely movably disposed. The driving part 63 includes a motor 69 and a converter 70. The motor 69 generates a rotational driving force. The converter 70 is provided to connect the motor 69 and the opening/closing part 62 and converts the rotational driving force generated by the motor 69 into a transverse driving force. The driving part 63 communicates/interrupts the upper opening 65 to/from the lower opening 66 by converting the rotational driving force of the motor 69 into the transverse driving force and moving the opening/closing part 62 transversely.

The purge gas introduction part 64 introduces purge gas into the first exhaust passage 56 through a gap between the opening/closing part 62 and the opening 61 under a state where the first opening/closing valve 60 is opened. As described above with reference to FIG. 2, the purge gas introduction part 64 is connected to the purge gas supplying unit 50 via the purge gas supplying passage 52. This allows the purge gas supplying unit 50 to join the exhaust passage 55 via the first opening/closing valve 60. A valve 53 to communicate/interrupt the purge gas introduction part 64 to/from the purge gas supplying unit 50 is disposed in the course of the purge gas supplying passage 52.

The first opening/closing valve 60 in some instances is set to the temperature of 200 degrees C. or more and as high as possible to prevent the product including PMDA and ODA from adhering to the valve 60. In this embodiment, the first opening/closing valve 60 is set from 200 to 260 degrees C. in consideration of heat resistance. In addition, the opening 61 in some instances has a diameter as large as possible as to not decrease conductance.

As described above with reference to FIG. 2, the pressure gauge 51 is disposed in the course of the purge gas supplying passage 52 through which purge gas flows from the purge gas supplying unit 50 into the exhaust passage 55. A pipe diameter of the purge gas supplying passage 52 is set to be small in the portion where the pressure gauge 51 is disposed. As a result, if exhaust gas flows backward toward the purge gas supplying passage 52, an extracted product may adhere to the inner side of a pipe of the purge gas supplying passage 52, which may result in blocking of the pipe. Accordingly, it is preferable that a passage in the purge gas introduction part 64 has a shape and flow rate to prevent the exhaust gas from flowing backward from the first opening/closing valve 60 into the purge gas introduction part 64. Further, it is preferable that the flow of purge gas is a turbulent flow and a flow speed of the purge gas does not exceed the speed of sound in the purge gas introduction part 64.

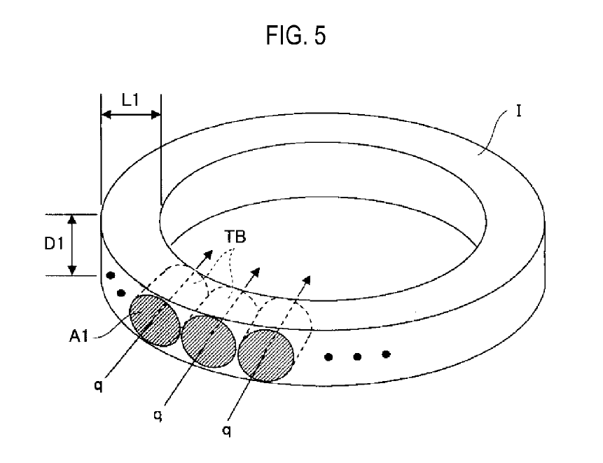

Hereinafter, a preferred range of shapes and flow rates to prevent the exhaust gas from flowing backward into the purge gas introduction part 64 will be described with reference to FIGS. 4 and 5. FIG. 5 is a perspective view showing a purge gas passage space model assumed for the calculation of a flow rate.

It is assumed that purge gas flows through a region (i.e., a doughnut-like passage space) I surrounded by a dashed line in FIG. 4 and sandwiched between the upper opening 65 and the lower opening 66 from an outer circumference toward an inner circumference. Here, the distance between the upper opening 65 and the lower opening 66 is denoted by D(m) and the width of the upper opening 65 and the lower opening 66 in a diametric direction is denoted by L(m). However, in FIGS. 4 and 5, in order to distinguish them from a second embodiment which will be described later, the gap D(m) and the width L(m) are replaced with D1 and L1, respectively. The passage space I is divided into a plurality of supplying pipes TB, each of which extends along the diametric direction of the periphery of the upper opening 65 and the lower opening 66 and has a pipe diameter (inner diameter) D1(m) and a pipe length (length) L1(m). That is, it is assumed that the passage space I is composed of N supplying pipes TB arranged along the circumferential direction of the upper opening 65 and the lower opening 66, each of which extends along the diametric direction of the upper opening 65 and the lower opening 66. For each supplying pipe TB, pressure, temperature, flow rate, flow speed and the speed of sound are denoted by P (Pa), T (K), Q (sccm), V (m/sec) and a (m/sec), respectively. At this time, a preferred range for distance D (=D1) and flow rate Q (sccm) to prevent exhaust gas from flowing backward into the purge gas introduction part 64 is obtained.

In the model of FIG. 5, when a sectional area of each supplying pipe TB and the number of supplying pipes TB are denoted by A1 and N, respectively, V=Q/(N×A1). That is, the flow rate Q corresponds to a value obtained by multiplying a flow rate q per supplying pipe TB (expressed by V×A1) by N.

First, the pressure P, temperature T and length L (L1) are assumed as follows:

Pressure: P=10 Pa

Temperature: T=400 K

Length: L=L1=0.004 m

In order to achieve a turbulent flow of purge gas in the purge gas introduction part 64, it is preferable that the Reynolds number Re expressed by the following Equation 1 exceeds 4000, as expressed by the following Equation 2.

Re=VL/v [Equation 1]

Re>4000 [Equation 2]

Where, v is the kinematic viscosity (m²/s) of the purge gas and is set to 4.05×10⁻⁵ (m²/s) for 400 K and 10 Pa in this embodiment.

In addition, in order to prevent the flow speed of the purge gas from exceeding the speed of sound, using the speed of sound a (m/sec) expressed by the following Equation 3, it is preferable that the Mach number Mach expressed by the following Equation 4 is less than 1, as expressed by the following Equation 5.

a=(kRT)^{0.5} [Equation 3]

Mach=V/a [Equation 4]

Mach<1 [Equation 5]

Where, k is the Boltzmann constant of 1.38×10⁻²³ J/K, R is 8.31 J/K/mol, and the speed of sound a is 4.08×10² m/sec for the temperature T.

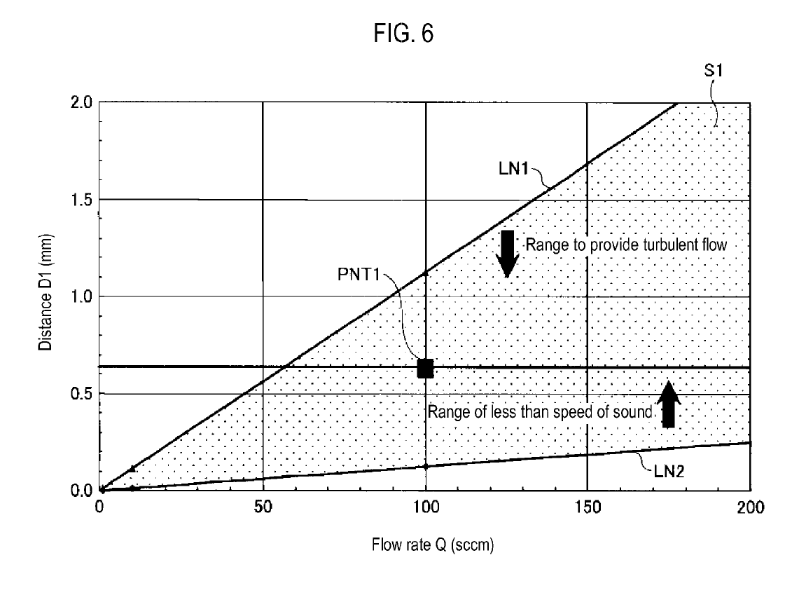

FIG. 6 is a graph showing a region satisfying Equations 2 and 5, where a horizontal axis represents a flow rate Q and a vertical axis represents a distance D1. In FIG. 6, a line LN1 indicates Re equal to 4000 and a line LN2 indicates V equal to a. In this case, a region below the line LN1 corresponds to a range to provide a turbulent flow as a region satisfying Equation 2. A region above the line LN2 corresponds to a range of less than the speed of sound as a region satisfying Equation 5. As a result, a shaded region S1 defined between the lines LN1 and LN2 corresponds to a region satisfying both of Equations 2 and 5.

For example, a set point PNT1 with a flow rate Q of 100 sccm and a distance D1 of 0.625 mm is included in the region S1. Accordingly, by setting the flow rate Q and the distance D1 to 100 sccm and 0.625 mm, respectively, it is possible to satisfy the conditions of shape and flow rate to prevent the exhaust gas from flowing backward into the purge gas introduction part 64.

As shown in FIG. 2, a heater 71 may be provided in the first opening/closing valve 60 to which the purge gas supplying unit 50 of the exhaust passage 55 is connected. The heater 71 is used to heat the first opening/closing valve 60. The heater 71 heats the first opening/closing valve 60 to a temperature above a range of temperatures in which a reaction for the extraction of a product is produced. Specifically, the first opening/closing valve 60 is heated to 200 to 260 degrees C. This can prevent a product including one or both of PMDA gas and ODA gas from being extracted and adhering to the interior of the first opening/closing valve 60, thereby preventing the interior of the first opening/closing valve 60 from being narrowed. The heater 71 corresponds to a heating mechanism in the present disclosure.

The control unit 80 includes, for example, a processing part, a storage part and a display part. The processing part is, for example, a computer with a CPU (Central Processing Unit). The storage part is a computer readable recording medium such as, for example, a hard disk, storing a program to cause the processing part to perform various processes. The display part is constituted by, for example, a computer screen. The processing part reads the program stored in the storage part, sends control signals to the supply mechanism 20, the vacuum pump 25, the trap unit 30, the purge gas supplying unit 50 and the pressure gauge 51, and performs a film forming process which will be described below.

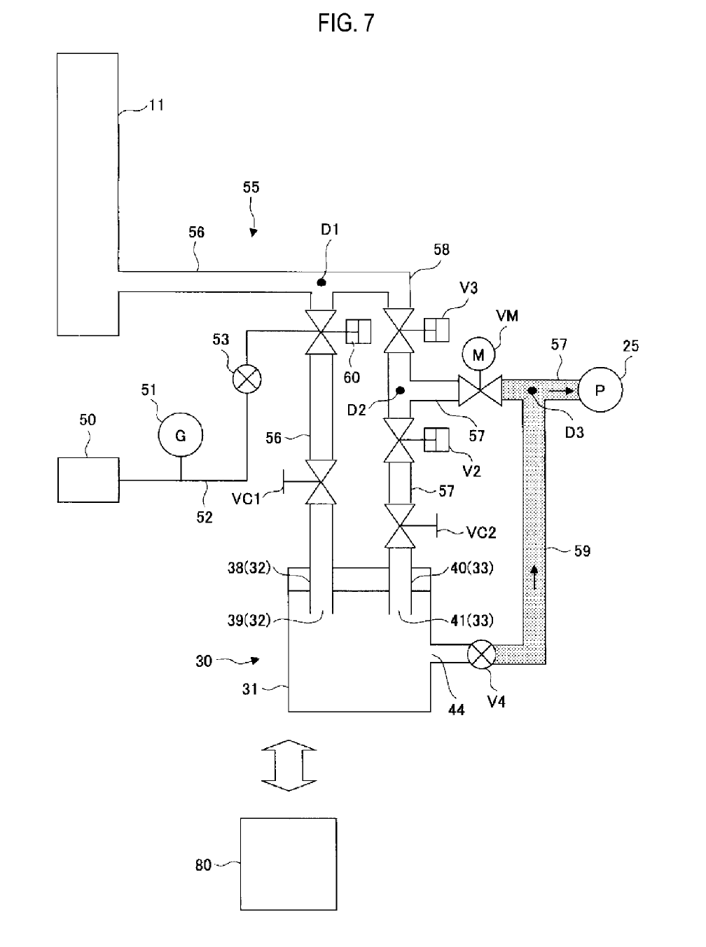

A film forming process performed by the film forming apparatus according to this embodiment will be now described by way of example with reference to FIGS. 7 to 10.

FIGS. 7 to 10 are views showing a state of exhaust passages and valves between the chamber 11 and the vacuum pump 25 in each step of a film forming process according to the first embodiment.

In FIGS. 7 to 10, for the purpose of convenience, an exhaust flow rate of an exhaust passage is divided into three parts: a white part of zero flow rate; a thinly shaded part of a lower flow rate; and a thickly shaded part of a higher flow rate. A part exhausted up to a high vacuum is thickly shaded like the thickly shaded part of a higher flow rate, irrespective of the later exhaust flow rate.

In addition, in FIGS. 7 to 10, an opening ratio of each of the first opening/closing valve 60, the second opening/closing valve V2, the third opening/closing valve V3 and the motor valve VM is divided into three states: a white state representing full valve close; a thinly shaded state representing regulated valve open; and a thickly shaded state representing full valve open.

The first control valve VC1 and the second control valve VC2 are constituted by, for example, a needle valve and their opening ratios are regulated in advance. These opening ratios may remain unchanged in the processes shown in FIGS. 7 to 10. Hereinafter, an example in which the regulated opening ratios of the first control valve VC1 and the second control valve VC2 remain unchanged will be described. In this example, the first control valve VC1 and the second control valve VC2 are indicated in white although they have the regulated valve opening ratios.

In the step shown in FIG. 7, with the fourth opening/closing valve V4 and the motor valve VM closed, a portion of the second exhaust passage 57 between the motor valve VM and the vacuum pump 25 and a portion of the fourth exhaust passage 59 between the fourth opening/closing valve V4 and the third branch point D3 are exhausted by the vacuum pump 25. At this time, as indicated by thick shading in FIG. 7, the portion of the second exhaust passage 57 between the motor valve VM and the vacuum pump 25 and the portion of the fourth exhaust passage 59 between the fourth opening/closing valve V4 and the third branch point D3 have a high flow rate. The thickly shaded portions in FIG. 7 are exhausted to a high vacuum of, for example, 10 Pa for a period of time of, for example, about 30 seconds.

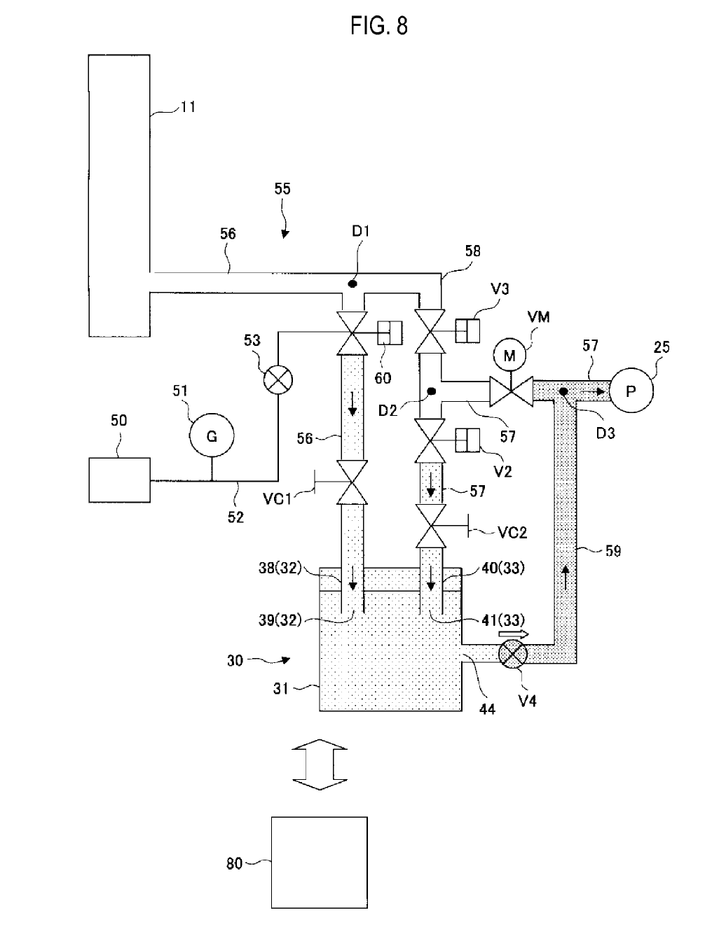

Subsequently, in the step shown in FIG. 8, the interior of the trap container 31 is initially exhausted. With the motor valve VM, the first opening/closing valve 60 and the second opening/closing valve V2 closed, the fourth opening/closing valve V4 is opened. Then, the interior of the trap container 31, a portion of the first exhaust passage 56 between the first opening/closing valve 60 and the trap container 31, and a portion of the second exhaust passage 57 between the second opening/closing valve V2 and the trap container 31 are exhausted by the vacuum pump 25. At this time, as indicated by thin shading in FIG. 8, the interior of the trap container 31, the portion of the first exhaust passage 56 between the first opening/closing valve 60 and the trap container 31, and the portion of the second exhaust passage 57 between the second opening/closing valve V2 and the trap container 31 have a low flow rate. The thinly shaded portions in FIG. 8 are exhausted to a high vacuum of, for example, 10 Pa for a period of time of, for example, about 120 minutes.

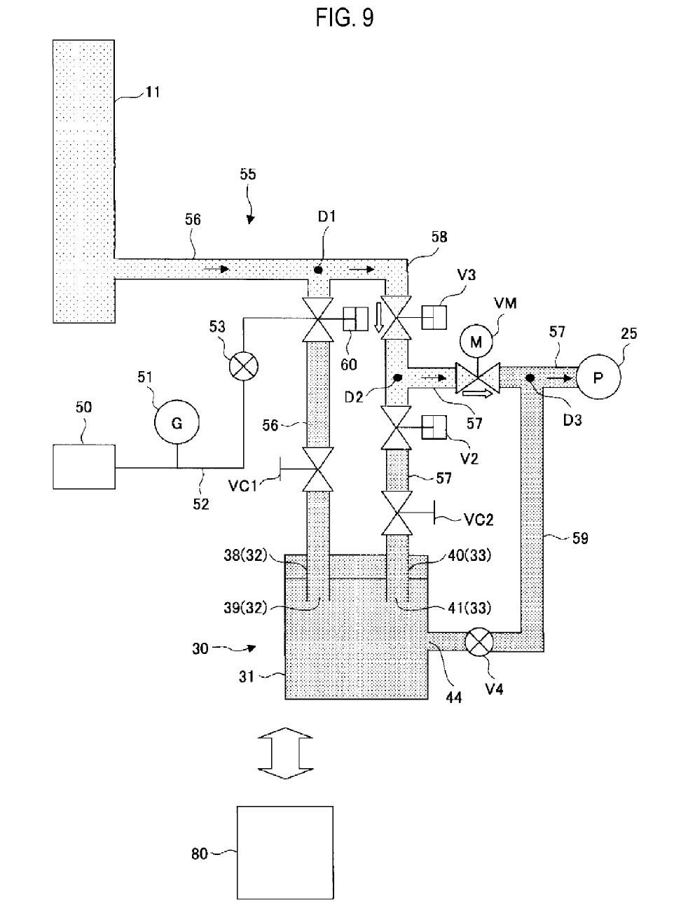

Prior to the step shown in FIG. 9, a wafer W is carried into the chamber 11. In the film forming apparatus 10 shown in FIG. 1, the wafer W may be carried into the chamber 11 by descending the wafer boat 12 to the lower and outer side of the chamber 11, loading the wafer W on the descended wafer boat 12, and ascending the wafer boat 12 with the wafer W to be inserted into the chamber 11.

Subsequently, in the step shown in FIG. 9, the interior of the chamber 11 is initially exhausted while interrupting the interior of the trap container 31 exhausted up to the high vacuum from the vacuum pump 25. With the first opening/closing valve 60 and the second opening/closing valve V2 closed, the opening ratio of the motor valve VM is regulated by closing the fourth opening/closing valve V4 and opening the third opening/closing valve V3. Then, a portion of the second exhaust passage 57 between the motor valve VM and the second opening/closing valve V2, the third exhaust passage 58, a portion of the first exhaust passage 56 between the first opening/closing valve 60 and the chamber 11, and the interior of the chamber 11 are exhausted by the vacuum pump 25. At this time, as indicated by thin shading in FIG. 9, the portion of the second exhaust passage 57 between the motor valve VM and the second opening/closing valve V2, the third exhaust passage 58, the portion of the first exhaust passage 56 between the first opening/closing valve 60 and the chamber 11, and the interior of the chamber 11 have a low flow rate. The thinly shaded portions in FIG. 9 are exhausted to a high vacuum of, for example, 10 Pa for a period of time of, for example, about 60 minutes.

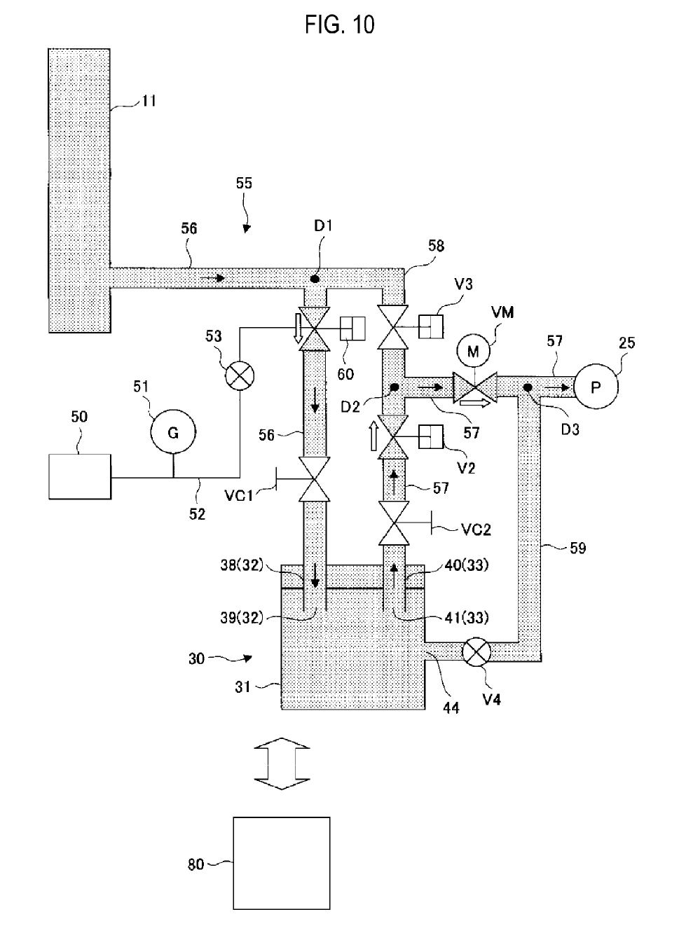

Subsequently, in the step shown in FIG. 10, the interior of the chamber 11 is exhausted up to a high vacuum. With the fourth opening/closing valve V4 closed, the third opening/closing valve V3 is closed and the motor valve VM, the second opening/closing valve V2 and the first opening/closing valve 60 are opened. Then, the interior of the chamber 11 is exhausted by the vacuum pump 25 through the second exhaust passage 57, the interior of the trap container 31 and the first exhaust passage 56. At this time, as indicated by thick shading in FIG. 10, the second exhaust passage 57, the interior of the trap container 31, the first exhaust passage 56 and the interior of the chamber 11 have a high flow rate. The thickly shaded portions in FIG. 10 are exhausted to a high vacuum of, for example, 1 Pa for a period of time of, for example, about 10 minutes.

After the step shown in FIG. 10, a polyimide film is formed. With the valve 23 opened, PMDA gas is supplied into the chamber 11 by means of the first raw material gas supplying unit 21. In addition, with the valve 24 opened, ODA gas is supplied into the chamber 11 by means of the second raw material gas supplying unit 22. Then, the polyimide film is formed by polymerization reaction of the PMDA gas and the ODA gas on the surface of the wafer W.

The polymerization reaction of the PMDA gas and the ODA gas is achieved according to the following chemical formula.

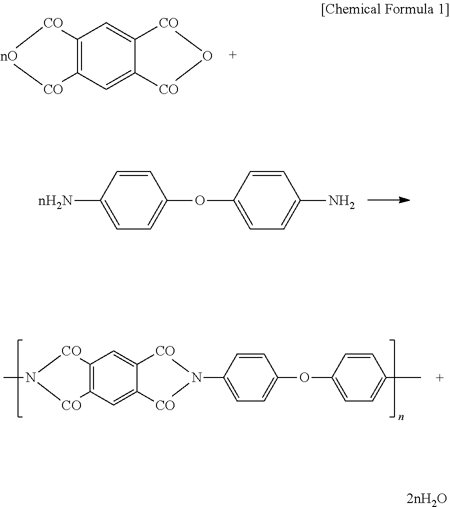

In forming the polyimide film, the internal pressure of the chamber 11 may be measured by the pressure gauge 51. Under the condition where the amount of PMDA gas and ODA gas is supplied by the supply mechanism 20, the controller 80 controls a displacement of the vacuum pump 25 based on the measured internal pressure of the chamber 11 such that the internal pressure of the chamber 11 reaches a predetermined pressure. As a result, the polyimide film can be stably formed.

Thereafter, with the third opening/closing valve V3 closed, the chamber 11 is interrupted from the vacuum pump 25 by closing the first opening/closing valve 60. Then, purge gas is supplied by a chamber purge gas supplying unit (not shown) and the internal pressure of the chamber 11 is returned to a predetermined pressure, for example, an atmospheric pressure (760 Torr). After the internal pressure of the chamber 11 is returned to the atmospheric pressure, the wafer W may be carried out of the chamber 11 by descending the wafer boat 12 to the lower and outer side of the chamber 11, removing the wafer W from the descended wafer boat 12, and ascending the wafer boat 12 without the wafer W to be inserted into the chamber 11.

Next, in comparison with a film forming apparatus according to a comparative example, description will be given to the properties of the film forming apparatus of this embodiment that the pressure gauge requires no heat resistance, an installation area is not increased, and a time interval for maintenance is substantially equal to that required when a pre-trap unit is provided.

The film forming apparatus 110 of the comparative example is different from the film forming apparatus of this embodiment in that a pre-trap unit 120 is provided in the first exhaust passage 56 between the chamber 11 and the first opening/closing valve 60, the pressure gauge 51 is directly connected to the first exhaust passage 56 and a gas escape unit 133 of a trap unit 130 is provided in the bottom portion 37 of the trap container 31. Therefore, explanation on other components except for the pre-trap unit 120, the pressure gauge 51 and the trap unit 130 will not be repeated.

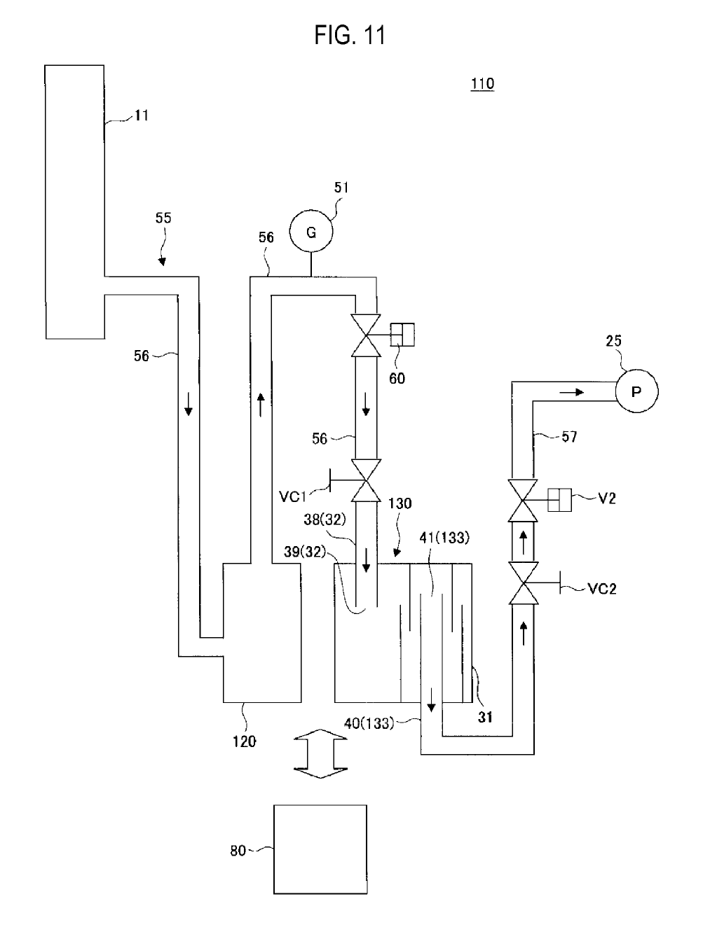

FIG. 11 is a schematic view showing detailed configuration between the chamber 11 and the vacuum pump 25 in the film forming apparatus 110 according to the comparative example.

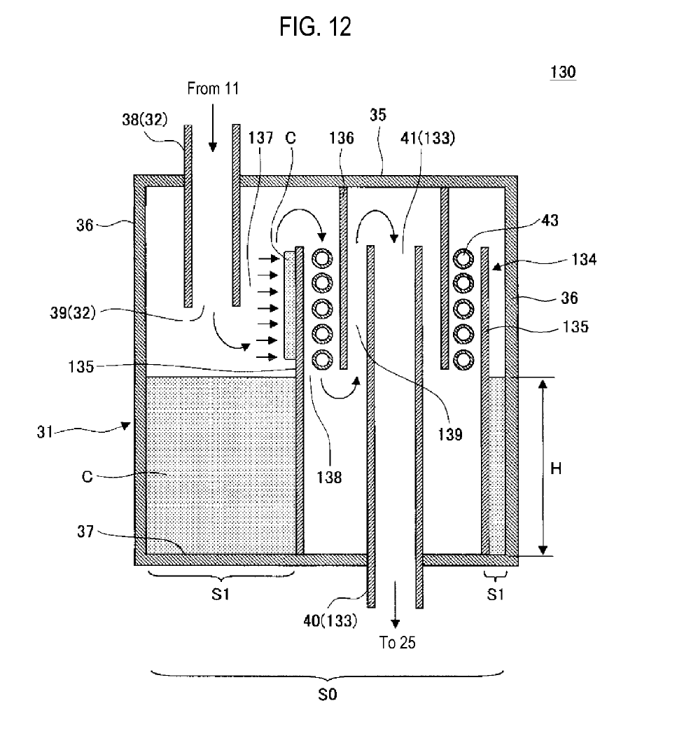

FIG. 12 is a longitudinal sectional view showing a configuration of the trap unit 130 in the film forming apparatus 110 according to the comparative example.

The pre-trap unit 120 is interposed between the chamber 11 and the first opening/closing valve 60. The pre-trap unit 120 is used to prevent a product from adhering to the interior of the pressure gauge 51 when the pressure gauge 51 is directly connected to the first exhaust passage 56 between the chamber 11 and the trap unit 130. The pre-trap unit 120 is also used to trap the product in advance between the chamber 11 and the pressure gauge 51.

The pre-trap unit 120 may have the same structure as the trap unit 130 which will be described later, or alternatively may have pins arranged in a multi-stage to be substantially perpendicular to a flow of gas inside a housing.

The pressure gauge 51 is directly connected to the first exhaust passage 56. Accordingly, the pressure gauge 51 requires heat resistance to a high temperature of, for example, about 200 degrees C.

Since the film forming apparatus 10 of this embodiment is not provided with a pre-trap unit, an installation area can be reduced by as much, as compared with the film forming apparatus of the comparative example. In addition, in this embodiment, the pressure gauge 51 is not directly connected to the first exhaust passage 56 but is disposed in the course of the purge gas supplying passage 52 joining the first exhaust passage 56. Accordingly, it is possible to provide a film forming apparatus which requires no heat resistance for the pressure gauge 51 and does not increase an installation area.

The trap unit 130 in the film forming apparatus of the comparative example includes a trap container 31, a gas introduction part 32, a gas escape part 133 and a partition part 134.

The trap container 31 includes a top portion 35, a side portion 36 and a bottom portion 37. The top portion 35, the side portion 36 and the bottom portion 37 are interconnected via, for example, an O-ring (not shown).

The gas introduction part 32 is disposed in the top portion 35 of the trap container 31 like the trap unit 30 of this embodiment. The gas introduction part 32 includes a gas introduction pipe 38 and a gas introduction hole 39.

The gas escape part 133 is disposed in the bottom portion 37 of the trap container 31 unlike in the trap unit 30 of this embodiment. The gas escape part 133 includes a gas escape pipe 40 and a gas escape hole 41. The gas escape pipe 40 is disposed to pass through the bottom portion 37 of the trap container 31 from top to bottom and the gas escape hole 41 opened in the trap container 31 is formed in the upper end of the gas escape pipe 40. The lower part of the gas escape pipe 40 is connected to the vacuum pump 25 and exhausts gas in the trap container 31 is exhausted to the vacuum pump 25 via the gas escape hole 41.

The partition part 134 includes partitions 135 and 136. The partition 135 is connected to the bottom portion 37 of the trap container 31, and the partition 136 is connected to the top portion 35 of the trap container 31. As a result, a passage 137 is defined by the inner side of the side portion 36 of the trap container 31 and the partition 135, a passage 138 is defined by the partition 135 and the partition 136, and a passage 139 is defined by the partition 136 and the gas escape pipe 40.

A water cooling pipe 43 as a cooling mechanism is disposed in the passage 138. The water cooling pipe 43 acts to cool exhaust gas.

A mixture of PMDA gas and ODA gas introduced into the trap container 31 through the gas introduction hole 39 flows upward through the passage 137 defined by the side portion 36 of the trap container 31 and the partition 135. Thereafter, the mixture gas flows downward through the passage 138 defined by the partition 135 and the partition 136.

In the comparative example, since the partition 135 is also cooled by the water cooling pipe 43, the mixture of PMDA gas and ODA gas flowing through the passage 137 is frozen at a side of the partition 135 in the passage 137 and is extracted as a product C. The extracted product C peels off from the side of the partition 135 and drops and deposits on the bottom portion 37 of the trap container 31 between the side portion 36 and the partition 135.

That is, in the comparative example, almost no product is deposited in a portion surrounded by the partition 135 on the bottom portion 37 of the trap container 31. Accordingly, when an area of the bottom portion 37 is denoted by S0, an area of a portion surrounded by the side portion 36 and the partition 135 is denoted by S1 and a deposition height of the product C during maintenance is denoted by H, a volume of the product which can be deposited is S1×H.

On the contrary, in this embodiment, a product is deposited on the entire surface of the bottom portion 37 of the trap container 31. Accordingly, when an area of the bottom portion 37 is denoted by S0 and a deposition height of the product C during maintenance is denoted by H, the volume of depositable product is SOxH.

For example, it is assumed that S1 is set to be half of S0 and the volume of depositable product in the pre-trap unit 120 of the comparative example is approximately equal to the volume of depositable product in the trap unit 130. Then, the volume of depositable product (hereinafter simply referred to as “volume”) in the trap unit 30 of this embodiment is approximately equal to the sum of the volume in the trap unit 130 and the volume in the pre-trap unit 120 of the comparative example. That is, in this embodiment providing no pre-trap unit, by disposing the gas introduction part 32 and the gas escape part 33 of the trap unit 30 on the top portion 35 of the trap container 31, the time interval for maintenance can be substantially equal to that required when a pre-trap unit is provided.

An evaluation on whether a pressure measured by the pressure gauge 51 in the film forming apparatus of this embodiment follows a change in the internal pressure of the chamber 11 and can be stably measured was performed. A result of the evaluation will be described below.

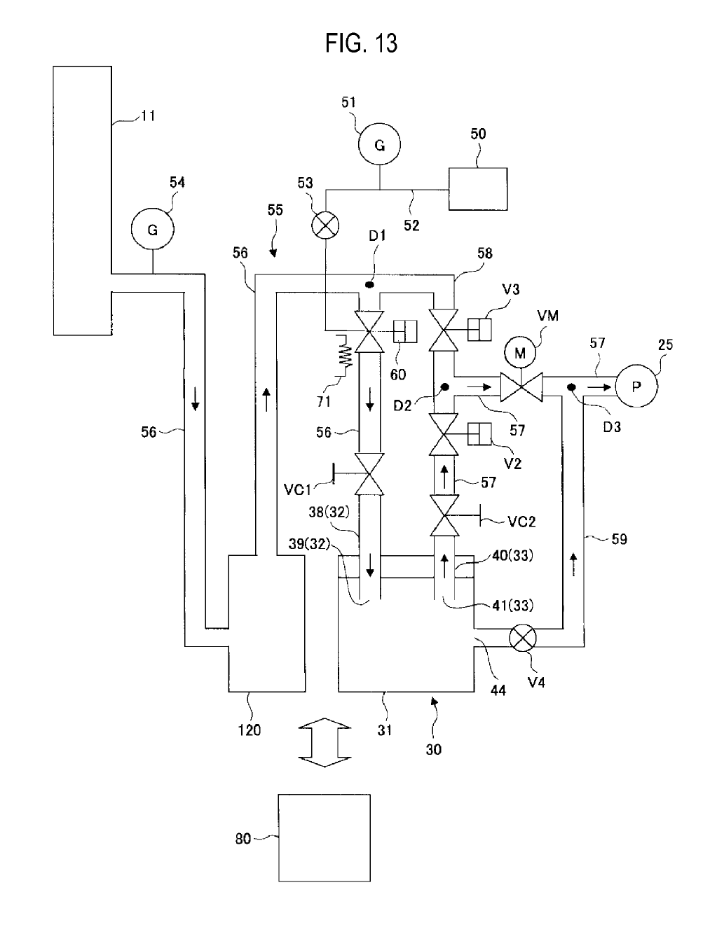

FIG. 13 is a schematic view showing detailed configuration between the chamber 11 and the vacuum pump 25 in an evaluated film forming apparatus.

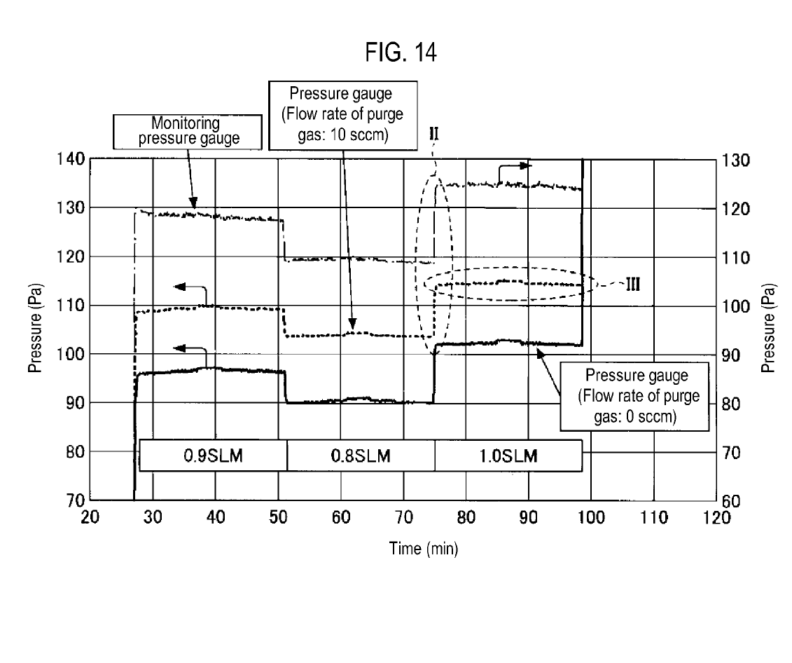

In the evaluated film forming apparatus, a pre-trap unit 120 is interposed between the chamber 11 and the first opening/closing valve 60 in the course of the first exhaust passage 56, in the film forming apparatus of this embodiment. A monitoring pressure gauge 54 is disposed near the chamber 11 in the course of the first exhaust passage 56. Then, with the interior of the chamber 11 exhausted as described above with reference to FIG. 10, pressures are measured by the monitoring pressure gauge 54 and the pressure gauge 51 when carrier gas flows from the supply mechanism 20 and a flow rate of the carrier gas is changed. FIG. 14 is a graph showing the temporal dependencies of the measured pressures.

FIG. 14 shows a temporal dependency of the pressure measured by the monitoring pressure gauge 54, a temporal dependency of the pressure measured by the pressure gauge 51 when a flow rate of purge gas from the purge gas supplying unit 50 is 10 sccm, and a temporal dependency of the pressure measured by the pressure gauge 51 when a flow rate of purge gas from the purge gas supplying unit 50 is 0 sccm. In this figure, the pressure measured by the pressure gauge 51 is represented by a left vertical axis and the pressure measured by the monitoring pressure gauge 54 is represented by a right vertical axis. In addition, a flow rate of carrier gas (in the unit of SLM) is shown in FIG. 14. For example, as indicated in a region II surrounded by a dashed line, when the flow rate of carrier gas is increased from 0.8 SLM to 1.0 SLM, the pressure measured by the pressure gauge 51 increases at nearly the same time when the pressure measured by the monitoring pressure gauge 54 increases. In addition, for example, as indicated in a region III surrounded by a dashed line, when the flow rate of carrier gas is constant, the pressure measured by the pressure gauge 51 is approximately equal to the pressure measured by the monitoring pressure gauge 54. Accordingly, it can be seen that the pressure measured by the pressure gauge 51 disposed in the course of the purge gas supplying passage 52 follows a change in the internal pressure of the chamber 11 and can be stably measured, like the pressure measured by the monitoring pressure gauge 54 disposed near the chamber 11 in the course of the first exhaust passage 56.

### Second Embodiment

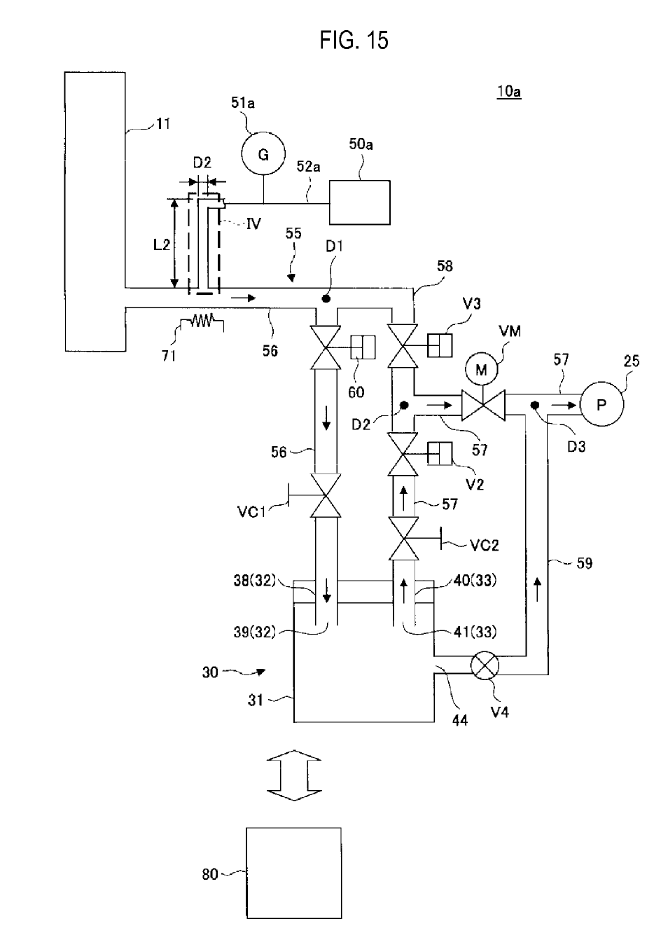

Next, a film forming apparatus according to a second embodiment of the present disclosure will be described with reference to FIG. 15.

The film forming apparatus according to this embodiment is different from the film forming apparatus according to the first embodiment in that the purge gas supplying unit is not connected to join the exhaust passage via the first opening/closing valve. Other portions are the same as those in the film forming apparatus of the first embodiment and therefore explanation thereof will not be repeated.

FIG. 15 is a schematic view showing detailed configuration between the chamber 11 and the vacuum pump 25 in a film forming apparatus 10a according to the second embodiment.

In this embodiment, a purge gas supplying unit 50a is not connected to join the first exhaust passage 56 via the first opening/closing valve 60. However, the purge gas supplying unit 50a is connected near the chamber 11 of the first exhaust passage 56. That is, the purge gas supplying unit 50a is connected to join the first exhaust passage 56 between the chamber 11 and the first opening/closing valve 60.

Also in this embodiment, a pressure gauge 51a is disposed in the course of a purge gas supplying passage 52a through which purge gas flows from the purge gas supplying unit 50a into the first exhaust passage 56. A pipe diameter of the purge gas supplying passage 52a is set to be small in the portion where the pressure gauge 51a is disposed. As a result, if exhaust gas flows backward toward the purge gas supplying passage 52a, an extracted product may adhere to the inner side of a pipe of the purge gas supplying passage 52a, which may result in blocking of the pipe. Accordingly, it is preferable that the purge gas supplying passage 52a has a shape and flow rate for preventing the exhaust gas from flowing backward from the first exhaust passage 56 into the purge gas supplying passage 52a. Further, it is preferable that a flow of purge gas is a turbulent flow and a flow speed of the purge gas does not exceed the speed of sound in the purge gas supplying passage 52a.

Hereinafter, a preferred range of shapes and flow rates for preventing the exhaust gas from flowing backward into the purge gas supplying passage 52a will be described.

In a region IV surrounded by a dashed line in FIG. 15, it is assumed that purge gas is supplied into the first exhaust passage 56 through a supplying pipe IV having a pipe diameter (inner diameter) corresponding to the pipe diameter D(m) of the purge gas supplying passage 52a and a length corresponding to the pipe length L(m) of the purge gas supplying passage 52a. However, in FIG. 15, in order to distinguish the present embodiment from the above-described first embodiment, the inner diameter D(m) and the length L(m) are replaced with D2 and L2, respectively. For the supplying pipe IV, pressure, temperature, flow rate, flow speed and the speed of sound are denoted by P (Pa), T (K), Q (sccm), V (m/sec) and a (m/sec), respectively. At this time, a preferred range for length L (=L2) and flow rate Q (sccm) for preventing exhaust gas from flowing backward into the purge gas supplying passage 52a is obtained.

When a sectional area of the supplying pipe IV is denoted by A2, V=Q/A2.

First, the pressure P, temperature T and inner diameter D are assumed as follows:

Pressure: P=10 Pa

Temperature: T=400 K

Inner diameter: D=D2=0.010 m

In order to achieve a turbulent flow of purge gas in the purge gas supplying passage 52a, it is preferable that the Reynolds number Re expressed by the above Equation 1 exceeds 4000, as expressed by the above Equation 2.

In addition, in order to prevent the flow speed of the purge gas from exceeding the speed of sound, using the speed of sound a (m/sec) expressed by the above Equation 3, it is preferable that the Mach number Mach expressed by the above Equation 4 is less than 1, as expressed by the above Equation 5.

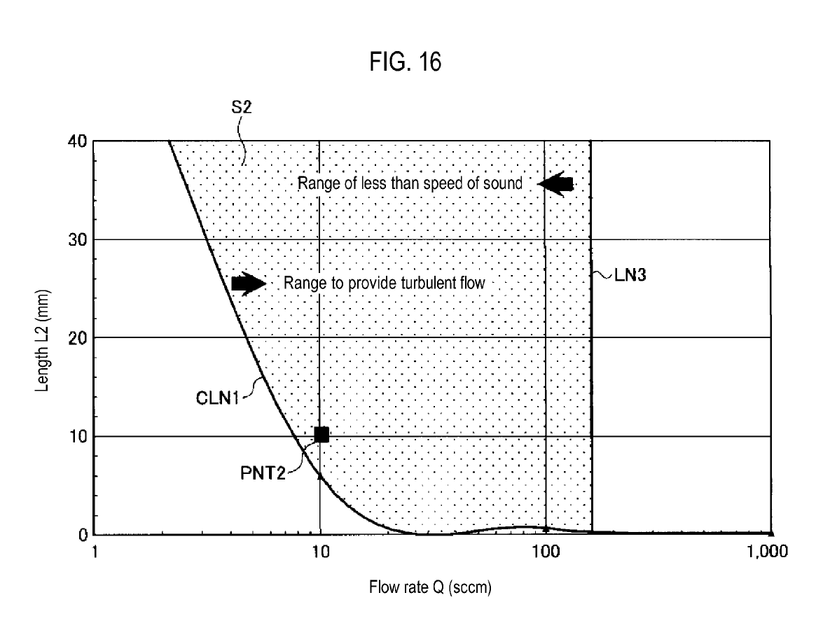

FIG. 16 is a graph showing a region satisfying Equations 2 and 5, where a horizontal axis represents a flow rate Q and a vertical axis represents a length L2. In FIG. 16, a curve CLN1 indicates Re equal to 4000 and a line LN3 indicates V equal to a. In this case, a region to the right side of the curve CLN1 corresponds to a range to provide a turbulent flow as a region satisfying Equation 2. A region to the left side of the line LN3 corresponds to a range of less than the speed of sound as a region satisfying Equation 5. As a result, a shaded region S2 defined between the curve CLN1 and the line LN3 corresponds to a region satisfying both of Equations 2 and 5.

For example, a set point PNT2 with a flow rate Q of 10 sccm and a length L2 of 10 mm is included in the region S2. Accordingly, by setting the flow rate Q and the length L2 to 10 sccm and 10 mm, respectively, it is possible to satisfy the conditions of shape and flow rate for preventing the exhaust gas from flowing backward into the purge gas supplying passage 52a.

A heater 71 may be provided in a part to which the purge gas supplying unit 50a of the first exhaust passage 56 is connected. The heater 71 heats the part to which the purge gas supplying unit 50a of the first exhaust passage 56 is connected to a temperature above a range of temperatures in which a reaction for the extraction of a product is produced. This can prevent a product including one or both of PMDA gas and ODA gas from being extracted and adhering to the interior of the part to which the purge gas supplying unit 50a of the first exhaust passage 56 is connected, thereby preventing the interior of the part from being narrowed.

Since the film forming apparatus 10a of this embodiment is also not provided with a pre-trap unit, an installation area can be reduced by as much. In addition, the pressure gauge 51a is not directly connected to the first exhaust passage 56 but is disposed in the course of the purge gas supplying passage 52a joining the first exhaust passage 56. Accordingly, it is possible to provide a film forming apparatus which requires no heat resistance for the pressure gauge 51a and does not increase an installation area.

In addition, in this embodiment providing no pre-trap unit, by disposing the gas introduction part 32 and the gas escape part 33 of the trap unit 30 in the top portion 35 of the trap container 31, the time interval for maintenance can be substantially equal to that required when a pre-trap unit is provided.

According to the present disclosure in some embodiments, it is possible to provide a film forming apparatus which requires no heat resistance for a pressure gauge for measuring an internal pressure of a film forming container and can achieve a decreased installation area.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

For example, although the film forming apparatus which forms a film on a wafer by supplying a first raw material gas obtained by vaporizing a first raw material composed of aromatic acid dianhydride and a second raw material gas obtained by vaporizing a second raw material composed of aromatic diamine in a film forming container has been illustrated in the above embodiments, the first raw material is not limited to aromatic acid dianhydride and the second raw material is not limited to aromatic diamine.

In addition, although the film forming apparatus which forms a film on a wafer by supplying a first raw material gas and a second raw material gas in a film forming container has been illustrated in the above embodiments, the present disclosure is not limited to the two kinds of raw materials. The present disclosure may be applied to a film forming apparatus which forms a film on a wafer by supplying only one kind of raw material.

What is claimed is:

1. A film forming apparatus which forms a film on a substrate held within a film forming container by supplying raw material gas onto the substrate, comprising:
a supply mechanism which supplies the raw material gas into the film forming container;
an exhaust mechanism which exhausts gas from the film forming container;
a trap unit which is disposed in the course of an exhaust passage through which gas flows from the film forming container to the exhaust mechanism, and traps the raw material gas by extracting a product containing the raw material gas;
a purge gas supplying unit which is connected to join the exhaust passage between the film forming container and the trap unit and supplies purge gas into the exhaust passage; and
a pressure gauge which is disposed in the course of a purge gas supplying passage through which the purge gas flows from the purge gas supplying unit into the exhaust passage.

2. The film forming apparatus of claim 1, further comprising an opening/closing valve unit which is disposed in the course of the exhaust passage and communicates/interrupts the film forming container to/from the trap unit,
wherein the purge gas supplying unit is connected to join the exhaust passage via the opening/closing valve unit.

3. The film forming apparatus of claim 1, wherein the trap unit includes:
a trap container;
a gas introduction part which introduces gas into the trap container;
a gas escape part which exhausts gas from the trap container; and
a trap plate which is substantially horizontally disposed within the trap container at a vertical position higher than a vertical position at which gas is introduced from the gas introduction part, and traps the raw material gas by cooling the introduced gas to extract the product containing the raw material gas.

4. The film forming apparatus of claim 1, further comprising a heating mechanism which heats a part to which the purge gas supplying unit of the exhaust passage is connected to a temperature above a range of temperatures in which a reaction for extraction of the product is produced.

5. The film forming apparatus of claim 1, wherein a Reynolds number of a purge gas flowing through the purge gas supplying passage exceeds 4000 and a Mach number of the purge gas flowing through the purge gas supplying passage is less than 1.

6. The film forming apparatus of claim 1, wherein the raw material gas contains aromatic acid dianhydride and aromatic diamine.
